(19) United States
(12) Patent Application Publication
(10) Pub. No.: US 2015/0077960 A1
(43) Pub. Date: Mar. 19, 2015

(54) LOW-TEMPERATURE PACKAGING METHODOLOGY FOR ELECTRONIC DEVICES AND OTHER DEVICES

(71) Applicant: Simon Gonzales, Phoenix, AZ (US)

(72) Inventor: Simon Gonzales, Phoenix, AZ (US)

(73) Assignee: Murata Manufacturing Co., Ltd., Nagaokakyo-shi (JP)

(21) Appl. No.: 14/031,860

(22) Filed: Sep. 19, 2013

(51) Int. Cl. H05K 1/18; B23K 37/00; B23K 1/00; H05K 13/04

(52) U.S. Cl. CPC H05K 1/185; H05K 13/0465; B23K 37/00; B23K 1/0016; H05K 2201/0104; B23K 2001/12
USPC 361/764; 361/761; 29/592.1; 148/528

(57) ABSTRACT

A method includes depositing a metal seal material onto a first component of a protective module. The method also includes placing a second component of the protective module into contact with the metal seal material. The components of the protective module define a cavity configured to hold one or more devices. The method further includes heating the metal seal material to create a metal seal between the components of the protective module. In addition, the method includes depositing an outer metal material over and in contact with the metal seal. Heating the metal seal material to create the metal seal could include performing an anneal process with a peak temperature of about 150° C. to about 200° C. The method could optionally include alloying part of the metal seal with part of the outer metal material to create alloyed regions between the components of the protective module.

### TECHNICAL FIELD

This disclosure is generally directed to device packaging techniques. More specifically, this disclosure relates to a low-temperature packaging methodology for electronic devices and other devices.

### BACKGROUND

Electronic devices are routinely packaged in various structures to help protect the electronic devices. For example, integrated circuit devices can be placed within a protective enclosure, and a lid can be sealed to the protective enclosure. Ideally, this protects the integrated circuit devices from their ambient environment when placed into operation.

### SUMMARY

This disclosure provides a low-temperature packaging methodology for electronic devices and other devices.

In a first embodiment, a method includes depositing a metal seal material onto a first component of a protective module. The method also includes placing a second component of the protective module into contact with the metal seal material. The components of the protective module define a cavity configured to hold one or more devices. The method further includes heating the metal seal material to create a metal seal between the components of the protective module. In addition, the method includes depositing an outer metal material over and in contact with the metal seal.

In a second embodiment, an apparatus includes a protective module having multiple components defining a cavity and one or more devices within the cavity. The protective module also includes an inner metal seal between the components of the protective module and an outer metal material covering at least part of the protective module. The outer metal material is in contact with the metal seal.

In a third embodiment, a method includes depositing a metal seal material onto a first component of a protective module. The method also includes placing a second component of the protective module into contact with the metal seal material. The components of the protective module define a cavity configured to hold one or more devices. The method further includes heating the metal seal material to create a metal seal between the components of the protective module. Heating the metal seal material includes performing an anneal process having a peak temperature of about 150° C. to about 200° C. In addition, the method includes depositing an outer metal material over at least part of the protective module. The outer metal material is in contact with the metal seal, and at least part of the outer metal material is located around a gap between the components of the protective module.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIGS. 1A through 23 illustrate an example protective enclosure and lid of a protective module according to this disclosure;

FIGS. 3A through 6 illustrate an example low-temperature packaging methodology for electronic devices and other devices; and

FIG. 7 illustrates an example method for low-temperature packaging of electronic devices and other devices according to this disclosure.

### DETAILED DESCRIPTION

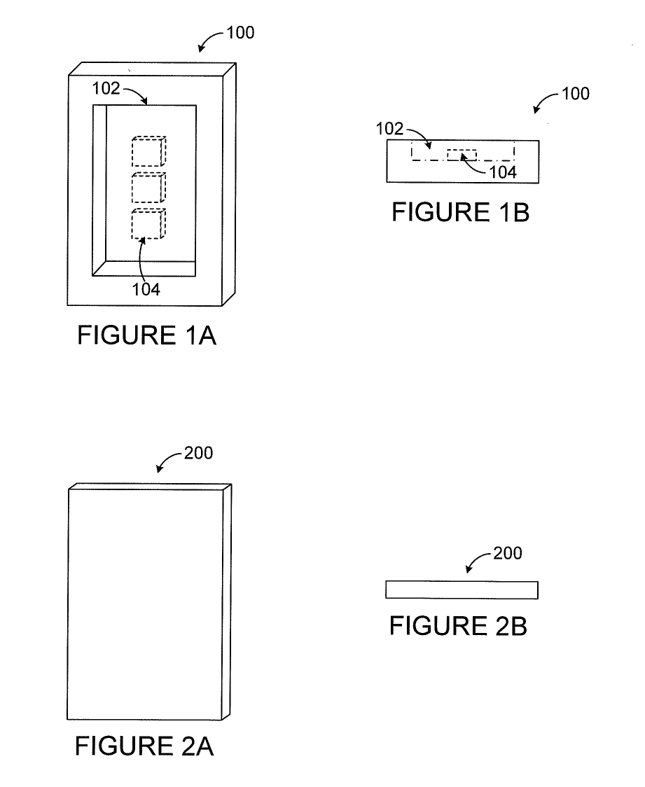

FIGS. 1 through 7, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

As noted above, electronic devices are routinely packaged in various structures, such as within protective enclosures that are sealed using lids. Unfortunately, a lid is often sealed to a protective enclosure at very high temperatures, such as a temperature of 330° C. or more. During such as process, various problems can be encountered. For example, high temperatures can affect materials with different coefficients of thermal expansion (CTEs), resulting in stress cracks, delamination, or morphology changes in the electronic devices. Also, epoxies or other materials that are routinely used to mount electronic devices can experience outgassing or shrinkage at high temperatures. In addition, high temperatures can alter the operational characteristics of the device being packaged, such as by causing shifts in the device's electrical parameters. Among other things, these shifts can be caused by material interactions, changes in junction doping, and electrical/material interactions.

This disclosure is directed to a low-temperature packaging methodology for electronic devices and other devices. The packaging methodology involves the use of a metal seal in a protective module and an outer metal. Optionally, metal mixing between the metal seal and the outer metal can be used to create an inter-metallic seal. The metal seal and the outer metal can be processed at reduced temperatures, which helps to avoid the various problems associated with high-temperature packaging techniques described above.

FIGS. 1A through 2B illustrate an example protective enclosure 100 and lid 200 of a protective module according to this disclosure. In particular, FIG. 1A represents a perspective view of the protective enclosure 100, and FIG. 1B represents an end view of the protective enclosure 100. In this example, the protective enclosure 100 generally denotes a structure that at least partially defines a cavity 102 into which one or more devices 104 can be inserted.

Note that while one cavity 102 and three devices 104 are shown here, any number of cavities and devices could be used. For example, one, two, or more than three devices 104 could be inserted into a single cavity 102. Also, the protective enclosure 100 could at least partially define multiple cavities 102 into which any number of devices 104 can be inserted.

The protective enclosure 100 could have any suitable size and shape. Similarly, the cavity 102 could have any suitable size and shape. While the protective enclosure 100 and the cavity 102 are each shown here as being generally rectangular, other shapes could be used, such as one with rounded corners. The protective enclosure 100 could be formed from any suitable material(s), such as stainless steel, steel/nickel, or other alloy(s). The protective enclosure 100 and the cavity 102 could also be formed in any suitable manner, such as by etching a piece of material to form the cavity 102 or by molding material into a suitable form.

FIG. 2A represents a perspective view of the lid 200, and FIG. 2B represents an end view of the lid 200. In this example, the lid 200 generally denotes a structure that is connected to the protective enclosure 100 in order to seal an open end of the cavity 102 and protect the device(s) 104 contained in the cavity 102.

The lid 200 could have any suitable size and shape. While the lid 200 is shown here as being generally rectangular, other shapes could be used, such as one with rounded corners. The lid 200 could be formed from any suitable material(s), such as stainless steel, steel/nickel, or other alloy(s). In addition, the lid 200 could be formed in any suitable manner, such as by etching or molding material into a suitable form.

As described in more detail below, the protective enclosure 100 and lid 200 form a protective module that protects the device(s) 104. The lid 200 is sealed against the protective enclosure 100 using a metal seal, such as a thin film of metal deposited around the raised portion of the protective enclosure 100. Also, an outer metal is deposited over at least a portion of the protective enclosure 100 and lid 200, where part of the outer metal contacts the inner metal seal between the protective enclosure 100 and lid 200. The metal seal and the outer metal could optionally mix at their interface to form an alloyed region.

Any suitable device(s) 104 can be inserted into the cavity 102 and protected by the protective module. For example, the device(s) 104 could include one or more integrated circuit chips. In these embodiments, the protective enclosure 100 could include or be coupled to a printed circuit board onto which the one or more integrated circuit chips are mounted, such as with an epoxy resin. However, the protective module could be used with any suitable component or components to be packaged. Example technology areas that can utilize the protective module include solar, automotive, and aerospace applications. Also, various micro-electro-mechanical-system (MEMS) structures could use the protective module. In addition, various components or subcomponents that require seals against ambient liquids or gasses could be used, such as in medical devices. The intended use of the device(s) 104 is one factor that can be used to select the metal(s) in the metal seal and the outer metal.

Note that the use of the term “seal” here does not require a hermetic or air-tight seal. Rather, a seal can be used to couple the protective enclosure 100 and lid 200 together. The seal may or may not represent a hermetic seal.

Although FIGS. 1A through 2B illustrate one example of a protective enclosure 100 and one example of a lid 200 of a protective module, various changes may be made to FIGS. 1A through 2B. For example, the lid 200 of the protective module is shown here as being an essentially monolithic block. However, this need not be the case. For instance, the lid 200 could define part of one or more cavities that, along with one or more cavities 102 of the protective enclosure 100, define the space for the device(s) 104. In fact, the one or more cavities 102 could be completely defined within the lid 200, and the protective enclosure 100 could be planar. In general, the protective enclosure 100 and the lid 200 could have any suitable configuration that defines at least one cavity when the protective enclosure 100 and the lid 200 are connected together.

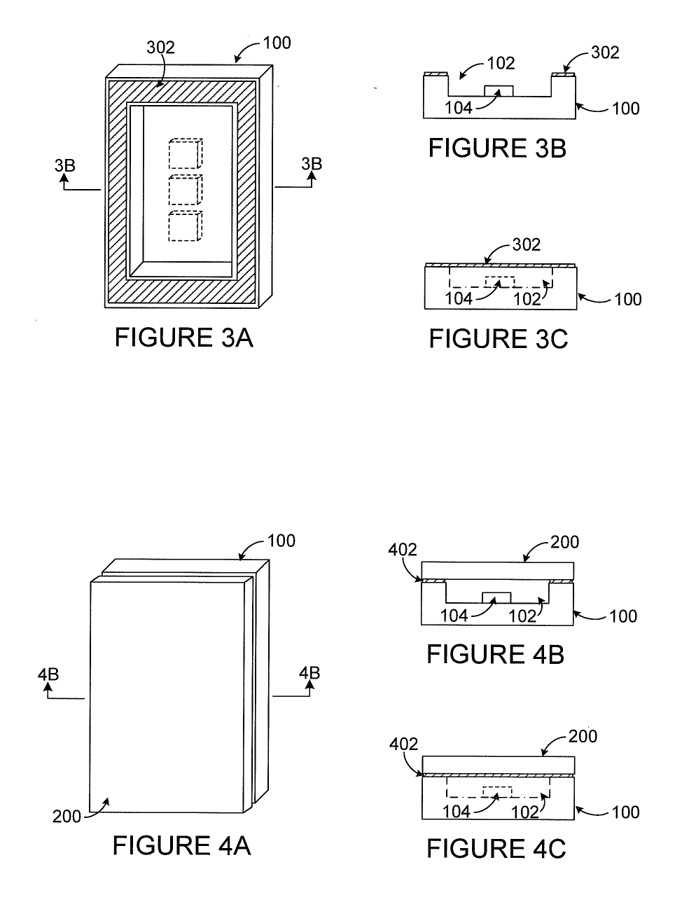

FIGS. 3A through 6 illustrate an example low-temperature packaging methodology for electronic devices and other devices. In particular, FIGS. 3A through 6 illustrate an example technique for packaging one or more electronic devices or other devices using a protective module that is formed with the protective enclosure 100 and the lid 200.

During the low-temperature packaging process, a surface preparation process can involve cleaning at least the “interface surfaces” of the protective enclosure 100 and the lid 200. The interface surfaces represent the surfaces of the protective enclosure 100 and the lid 200 that are sealed together using a metal seal. The surface preparation process could be accomplished in any suitable manner. For example, a plasma treatment that uses a combination of radio frequency (RF) or microwave power and gases such as argon and/or oxygen can be utilized to remove surface and organic contamination from at least portions of the protective enclosure 100 and the lid 200.

A metal seal material 302 is deposited on the protective enclosure 100 as shown in FIGS. 3A through 3C. FIG. 3A shows a perspective view of the protective enclosure 100 with the metal seal material 302. FIG. 3B illustrates a cross-sectional view of the protective enclosure 100 with the metal seal material 302 taken along line 3B-3B in FIG. 3A. FIG. 3C represents an end view of the protective enclosure 100 with the metal seal material 302.

The metal seal material 302 here represents a thin layer of at least one metal deposited onto the protective enclosure 100. The metal seal material 302 is used to form a seal in order to connect the protective enclosure 100 and the lid 200 at a relatively low temperature. The metal seal material 302 includes any suitable metal(s) for coupling components of a protective module. As specific examples, the metal seal material 302 could represent a metal alloy with a low melting point, such as a CERROSAFE or CERRO METAL alloy from ROTOMETALS, INC. The metal seal material 302 can also be deposited in any suitable manner, such as by using plasma vapor deposition (PVD), evaporation, or electroplating.

Note that in FIGS. 3A through 3C, the metal seal material 302 extends completely around the cavity 102 of the protective enclosure 100. This is for illustration only. In other embodiments, the metal seal material 302 need not extend completely around the cavity 102 of the protective enclosure 100. This may be possible, for example, when an air-tight seal of the cavity 102 is not required. Also note that the metal seal material 302 could additionally or alternatively be deposited on the lid 200.

At this point, the device(s) 104 can be inserted into the cavity 102 and mounted to the structure. For example, one or more integrated circuit chips can be secured using epoxy resin or other adhesive. As noted above, however, any suitable device(s) can be placed into one or more cavities 102 of the protective module.

The lid 200 is placed into contact with the metal seal material 302 and the metal seal material 302 is converted into a metal seal 402 as shown in FIGS. 4A through 4C. FIG. 4A shows a perspective view of the protective enclosure 100 with the metal seal 402 in contact with the lid 200. FIG. 4B illustrates a cross-sectional view of the protective enclosure 100 with the metal seal 402 in contact with the lid 200 taken along line 4B-4B in FIG. 4A. FIG. 4C represents an end view of the protective enclosure 100 with the metal seal 402 in contact with the lid 200.

The metal seal material 302 can be converted into the metal seal 402 by applying heat to the structure. For example, the entire structure can be placed into a furnace for an anneal process. The exact temperature and length of the anneal process can vary depending on various factors, including the type of material(s) used as the metal seal material 302. In some embodiments, the anneal process could occur at a temperature of about 150° C. to about 200° C. (although other temperatures could be used). Also, the peak temperature of the anneal process could occur at about two minutes to about ten minutes into the anneal process (although the peak temperature could occur at other times). The application of heat to the metal seal material 302 generally binds to the metal seal material 302 to the protective enclosure 100 and the lid 200, thereby connecting those components together and creating the metal seal 402.

At this point, the metal seal 402 may or may not be free of voids and therefore may or may not be a hermetic seal. However, regardless of its properties, the metal seal 402 successfully couples the lid 200 to the protective enclosure 100, and this is accomplished at substantially lower temperatures than conventional packaging techniques. As a result, the device(s) 104 within the cavity 102 are subjected to substantially lower temperatures during the packaging process, which helps to reduce or prevent the various problems discussed above.

Once again, note that in FIGS. 4A through 4C, the metal seal 402 extends completely around the cavity 102 of the protective enclosure 100. This is for illustration only. In other embodiments, the metal seal 402 need not extend completely around the cavity 102 of the protective enclosure 100. This may be possible, for example, when an air-tight seal of the cavity 102 is not required.

Another surface preparation operation can be performed to prepare the outer surface of the structure for additional processing steps. Any suitable surface preparation operation can occur here. For example, a plasma treatment using argon and/or oxygen can be utilized to remove surface and organic contamination.

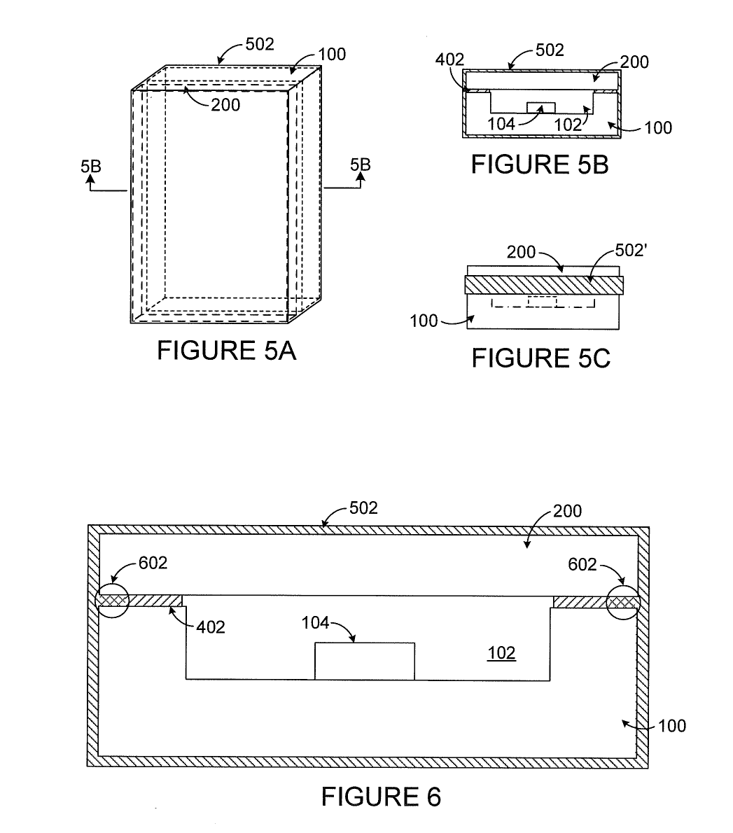

An outer metal material 502 or 502′ is deposited onto at least part of the protective enclosure 100 and lid 200 as shown in FIGS. 5A through 5C. FIG. 5A shows a perspective view of the protective enclosure 100 and lid 200 with the outer metal material 502. FIG. 5B illustrates a cross-sectional view of the protective enclosure 100 and lid 200 with the outer metal material 502 taken along line 5B-5B in FIG. 5A. FIG. 5C represents an end view of the protective enclosure 100 and lid 200 with the outer metal material 502′.

As shown in FIGS. 5A and 5B, the outer metal material 502 covers the entire protective enclosure 100 and lid 200. The outer metal material 502 could represent any suitable metal(s), such as a refractory metal like titanium, titanium nitride, tungsten, or platinum or a non-refractory metal like gold. The outer metal material 502 could be deposited in any suitable manner, such as PVD sputtering, evaporation, or electroplating. In particular embodiments, PVD sputtering is used, the metal from the PVD sputtering can be derived from a target that is properly alloyed, and a 1:1 deposition translation can be made to a surface. The outer metal material 502 can form a barrier seal that overlies the inner metal seal 402.

Because the outer metal material may only be needed in areas at or near the inner metal seal 402, the outer metal material can alternatively be deposited over portions (but not all) of the protective enclosure 100 and/or the lid 200. For example, the outer metal material 502′ can be deposited as shown in FIG. 5C, where the outer metal material 502′ is deposited only around the seam or gap that separates the protective enclosure 100 from the lid 200.

Depending on the materials used, the low-temperature packaging methodology could be completed upon deposition of the outer metal material 502 or 502′. For example, if a refractory metal is used as the outer metal material 502 or 502′ and functions as an air barrier, no other processing steps may be required to complete the packaging process.

In other embodiments, however, an additional processing step could cause the outer metal material 502 or 502′ to interact with the inner metal seal 402, thereby forming an alloy of the metals. This is shown in FIG. 6, where alloyed regions 602 denote areas where an alloy is formed between the outer metal material 502 or 502′ and the inner metal seal 402.

Any suitable technique could be used to trigger the mixing of the metals to create the alloyed regions 602. For example, a controlled anneal, sinter, or other heat treatment could be used, and the particular process could be selected or controlled based on the metals being alloyed. As a particular example, a rapid thermal anneal could be used to quickly raise the temperature around the structure and create enough heat to alloy portions of the outer metal material 502 or 502′ and the inner metal seal 402. The rapid thermal anneal could include heating the structure to temperatures of up to 1200° C., although higher or lower temperatures could be used. However, because the temperature rises rapidly and the anneal process may be completed quickly, the device(s) 104 within the structure may not experience such high temperatures, which again helps to reduce or prevent the various problems discussed above. The alloying of the outer metal material 502 or 502′ and the inner metal seal 402 helps to increase the integrity of the seal between the protective enclosure 100 and the lid 200, which can help lead to the simpler creation of a hermetic seal between the protective enclosure 100 and the lid 200.

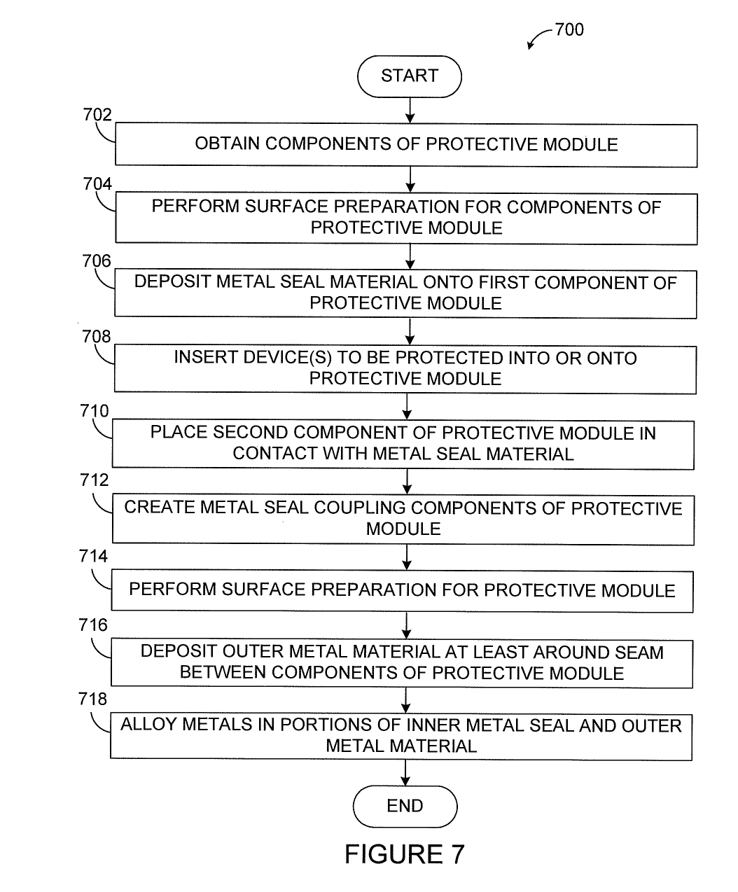

FIG. 7 illustrates an example method 700 for low-temperature packaging of electronic devices and other devices according to this disclosure. As shown in FIG. 7, components of a protective module are obtained at step 702. This could include, for example, fabricating, purchasing, or otherwise obtaining a protective enclosure 100 and a lid 200 of the protective module. Surface preparation for the components of the protective module occurs at step 704. This could include, for example, performing a plasma cleaning process to remove contaminants and other materials from the protective enclosure 100 and lid 200.

A metal seal material is deposited onto a first component of the protective module at step 706. This could include, for example, depositing the metal seal material 302 onto the protective enclosure 100. Note, however, that the metal seal material 302 could also or alternatively be deposited onto the lid 200.

One or more devices to be protected are inserted into or onto the protective module at step 708. This could include, for example, mounting one or more integrated circuit chips in at least one cavity 102 of the protective module using epoxy resin or other adhesive. As noted above, any other or additional device(s) could be mounted or positioned within the protective module.

A second component of the protective module is placed into contact with the metal seal material at step 710. This could include, for example, mounting the lid 200 on the metal seal material 302. As noted above, the metal seal material 302 could be placed on the lid 200, in which case the protective enclosure 100 can be placed into contact with the metal seal material 302.

A metal seal coupling the components of the protective module is formed at step 712. This could include, for example, heating the metal seal material 302 to create the metal seal 402. The heating of the metal seal material 302 can be done at a lower temperature compared to conventional packaging techniques.

Another surface preparation for the protective module occurs at step 714. This could include, for example, performing another plasma cleaning process to remove contaminants and other materials off the protective enclosure 100 and connected lid 200.

An outer metal material is deposited at least around a seam between the components of the protective module at step 716. This could include, for example, depositing the outer metal material 502 around the entire protective enclosure 100 and connected lid 200. This could also include depositing the outer metal material 502′ around only the area where the protective enclosure 100 and the connected lid 200 are separated by a gap. The outer metal material generally is deposited along most or all of the exposed portions of the metal seal 402, regardless of how much additional surfaces of the protective enclosure 100 and lid 200 are covered.

In some embodiments, the method 700 could end at this point. The outer metal material 502, 502′ could function as an air barrier, and the inner metal seal 402 can function to hold the enclosure 100 and lid 200 together. In other embodiments, the method 700 continues by alloying the metals in portions of the metal seal and the outer metal material at step 718. This could include, for example, heating the structure as part of a rapid thermal anneal or other heating process. The heating can cause the metal in part of the metal seal 402 to mix with the metal in part of the outer metal material 502, creating the alloyed regions 602. This alloying can help to increase the integrity of the seal between the protective enclosure 100 and the lid 200.

Although the figures have shown and described a low-temperature packaging methodology for electronic devices and other devices and such a package, various changes may be made to the figures. For example, as noted above, the protective enclosure 100 and lid 200 could have different size(s) and shape(s), and one or more cavities 102 of any suitable size(s) and shape(s) can be defined by the protective enclosure 100 and lid 200. Also, while the figures have generally shown a process for packaging, various stages or steps in the process could be reordered or repeated as needed or desired. In addition, while particular materials and fabrication steps have been described above, the low-temperature packaging methodology described here can involve the use of any suitable materials and any suitable processing steps to achieve the desired seal.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with” and its derivatives mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
depositing a metal seal material onto a first component of a protective module;
placing a second component of the protective module into contact with the metal seal material, wherein the components of the protective module define a cavity configured to hold one or more devices;
heating the metal seal material to create a metal seal between the components of the protective module; and
depositing an outer metal material over and in contact with the metal seal.

2. The method of claim 1, further comprising:
alloying part of the metal seal with part of the outer metal material to create alloyed regions between the components of the protective module.

3. The method of claim 2, wherein alloying part of the metal seal with part of the outer metal material comprises heating the protective module after deposition of the outer metal material.

4. The method of claim 3, wherein heating the protective module comprises performing a rapid thermal anneal.

5. The method of claim 2, wherein the alloyed regions form a hermetic seal.

6. The method of claim 1, wherein heating the metal seal material to create the metal seal comprises performing an anneal process.

7. The method of claim 6, wherein the anneal process comprises an anneal process with a peak temperature of about 150° C. to about 200° C.

8. The method of claim 1, wherein depositing the outer metal material comprises depositing the outer metal material over part but not all of the protective module.

9. The method of claim 1, wherein the depositing the metal seal material comprises depositing a thin layer of the metal seal material on the first component of the protective module, the thin layer deposited around at least a portion of the cavity.

10. The method of claim 1, wherein the outer metal material forms an air barrier.

11. An apparatus comprising:
a protective module comprising multiple components defining a cavity; and
one or more devices within the cavity;
wherein the protective module further comprises:
an inner metal seal between the components of the protective module; and
an outer metal material covering at least part of the protective module, the outer metal material in contact with the metal seal.

12. The apparatus of claim 11, wherein the protective module further comprises:
alloyed regions between the components of the protective module, the alloyed regions comprising metal from the metal seal and metal from the outer metal material.

13. The apparatus of claim 12, wherein the alloyed regions form a hermetic seal.

14. The apparatus of claim 11, wherein the outer metal material covers part but not all of the protective module.

15. The apparatus of claim 11, wherein the components of the protective module comprise:
a protective enclosure defining at least part of the cavity; and
a lid configured to cover an open end of the cavity.

16. The apparatus of claim 11, wherein the metal seal comprises a thin layer of metal around at least a portion of the cavity.

17. The apparatus of claim 11, wherein the outer metal material forms an air barrier.

18. The apparatus of claim 11, wherein the one or more devices comprise one or more integrated circuit chips.

19. A method comprising:
depositing a metal seal material onto a first component of a protective module;
placing a second component of the protective module into contact with the metal seal material, wherein the components of the protective module define a cavity configured to hold one or more devices;
heating the metal seal material to create a metal seal between the components of the protective module, wherein heating the metal seal material comprises performing an anneal process having a peak temperature of about 150° C. to about 200° C.; and
depositing an outer metal material over at least part of the protective module, the outer metal material in contact with the metal seal, at least part of the outer metal material located around a gap between the components of the protective module.

20. The method of claim 19, further comprising:
alloying part of the metal seal with part of the outer metal material to create alloyed regions between the components of the protective module;
wherein the alloyed regions form a hermetic seal.
